(19) United States
(12) Patent Application Publication
(10) Pub. No.: US 2026/0039328 A1
(43) Pub. Date: Feb. 5, 2026

(54) METHODS AND APPARATUS TO CHARACTERIZE CABLE FAULTS

(71) Applicant: Texas Instruments Incorporated, Dallas, TX (US)

(72) Inventors: Arihant Jain, Santa Clara, CA (US); Ashwin Ramachandran, Santa Clara, CA (US)

(21) Appl. No.: 18/789,310

(22) Filed: Jul. 30, 2024

(51) Int. Cl. H04B 3/46

(52) U.S. Cl. CPC H04B 3/46

(57) ABSTRACT

An example apparatus includes: controller circuitry configured to: instruct transmitter circuitry within a device to perform operations, the transmitter circuitry coupled to a cable interface terminal; responsive to the operations, instruct receiver circuitry within the device to measure a voltage, the receiver circuitry also coupled to the cable interface terminal; and determine, responsive to the measured voltage, when a fault exists on a cable that is coupled to the cable interface terminal.

### TECHNICAL FIELD

This description relates generally to cables, and, more particularly, to methods and apparatus to characterize cable faults.

### BACKGROUND

Modern vehicles often rely on a network of computational devices to perform various sensing and actuation tasks in a safe and reliable manner. In many examples, automotive manufactures use cables to implement wired connections to exchange data between devices. Cables may be advantageous over wireless communication in an automotive setting because wired connections generally enable faster data transfer and fewer transmission errors than wireless communication. To be considered safe for automotive use, a cable may be required to retain its quality while exposed to various amounts and types of mechanical stress, heat, oils, chemicals, and acids found in a vehicle.

### SUMMARY

For methods and apparatus to characterize cable faults, a first apparatus includes: transmitter circuitry having an input and an output; receiver circuitry having an input coupled to the output of the transmitter circuitry, and an output; and controller circuitry having an input coupled to the output of the receiver circuitry and an output coupled to the input of the transmitter circuitry; the controller circuitry configured to: instruct the transmitter circuitry to transmit a signal; and determine, responsive to a voltage at the output of the receiver circuitry after the transmission of the signal, when a fault exists in a cable coupled to the output of the transmitter circuitry.

A second example apparatus includes: controller circuitry configured to: instruct transmitter circuitry within a device to perform operations, the transmitter circuitry coupled to a cable interface terminal; responsive to the operations, instruct receiver circuitry within the device to measure a voltage, the receiver circuitry also coupled to the cable interface terminal; and determine, responsive to the measured voltage, when a fault exists on a cable that is coupled to the cable interface terminal.

An example system includes: serializer circuitry having an interface terminal; a cable having: a fault; a first terminal coupled to the interface terminal of the serializer circuitry; and a second terminal; and deserializer circuitry having an interface terminal coupled to the second terminal of the cable, the deserializer circuitry configured to determine: the fault exists within the cable; a type of the fault; and a location of the fault.

### BRIEF DESCRIPTION OF THE DRAWINGS

FIG. 1 is a block diagram of an example vehicle that includes an Electronic Control Unit (ECU) and camera circuitry.

FIG. 2 is a block diagram of an example implementation of the SerDes system of FIG. 1.

FIG. 3 is a block diagram of an example implementation of the deserializer circuitry and the serializer circuitry of FIG. 2.

FIG. 4 is a block diagram of an example implementation of the deserializer circuitry of FIG. 2.

FIG. 5 is a flowchart representative of example machine-readable instructions or example operations that may be at least one of executed, instantiated, or performed using an example programmable circuitry implementation of the controller circuitry of FIG. 3.

FIG. 6 is a flowchart representative of example machine-readable instructions or example operations that may be at least one of executed, instantiated, or performed to determine if a fault exists as described in FIG. 5.

FIG. 7 is a flowchart representative of example machine-readable instructions or example operations that may be at least one of executed, instantiated, or performed to diagnose a type of fault as described in FIG. 5.

FIG. 8 is a graph showing example outputs of the variable gain adapter circuitry as described in connection with FIG. 7.

FIG. 9 is a flowchart representative of example machine-readable instructions or example operations that may be at least one of executed, instantiated, or performed to determine a location of a fault as described in FIG. 5.

FIG. 10 is a block diagram of an example processing platform including programmable circuitry structured to execute, instantiate, or perform the example machine-readable instructions or perform the example operations of FIGS. 6, 7, and 9 to implement the deserializer circuitry 202 of FIGS. 3 and 4.

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

Cables can be used within a system to perform a multitude of application-specific roles. For example, Advanced Driver Assistance Systems (ADAS) environments include camera circuitry that provide images to control circuitry by providing data over a cable. In some examples, a manufacturer or designer of the automobile implements a coaxial cable between the camera circuitry and control circuitry to reduce cost relative to another cable format (e.g., Ethernet). The coaxial cable can be used to simultaneously: a) provide power the camera circuitry, b) provide forward-channel communication from the camera circuitry to the control circuitry, and c) provide back-channel communication from the control circuitry to the camera circuitry. Such a connection may be referred to as a Power over Coax (PoC) based Simultaneous Bi-Directional (SBD) serial link.

The use of existing PoC based SBD serial link protocols can prevent or mitigate the troubleshooting of ADAS functionality. For example, suppose the control circuitry expects to receive a new image from the camera circuitry at periodic intervals. The control circuitry can therefore identify that a fault has occurred if it does not receive an image at an expected timestamp. The control circuitry cannot, however, use existing protocols to determine whether the fault is caused by an issue on the camera circuitry, the coaxial cable, or the control circuitry. As a result, correction of the fault may require human investigation and the disabling of one or more ADAS features until a human can investigate the control circuitry, coaxial cable, and camera circuitry. Furthermore, existing PoC based SBD serial link protocols do not indicate where the fault occurred on the cable, or what type of fault occurred. Accordingly, a human operator must continue to manually investigate the cable in existing ADAS environments to determine how to fix the fault. Such manual troubleshooting is expensive and time consuming.

Example methods, apparatus, and systems described herein implement a protocol to automate cable troubleshooting operations that would otherwise be performed manually. An example vehicle includes serializer circuitry, a cable, and deserializer circuitry to implement an SBD serial link communications system. The deserializer circuitry disables forward-channel communications, sends a transmission signal across the coaxial cable, and measures any reflected signal that returns. The deserializer circuitry then uses the presence, amplitude, and other characteristics of the reflected signal to determine one or more of: whether a fault exists on the cable, whether the fault is an open circuit or a closed circuit, and where the fault is located on the cable. Accordingly, the deserializer circuitry described herein can troubleshoot cable faults with more detail, less time, and less complexity than other vehicle systems. While examples described above and below refer to a cable for simplicity, the automated troubleshooting operations described herein are more generally applicable to any kind of impedance discontinuity in a high-speed signal path, channel, or conductor.

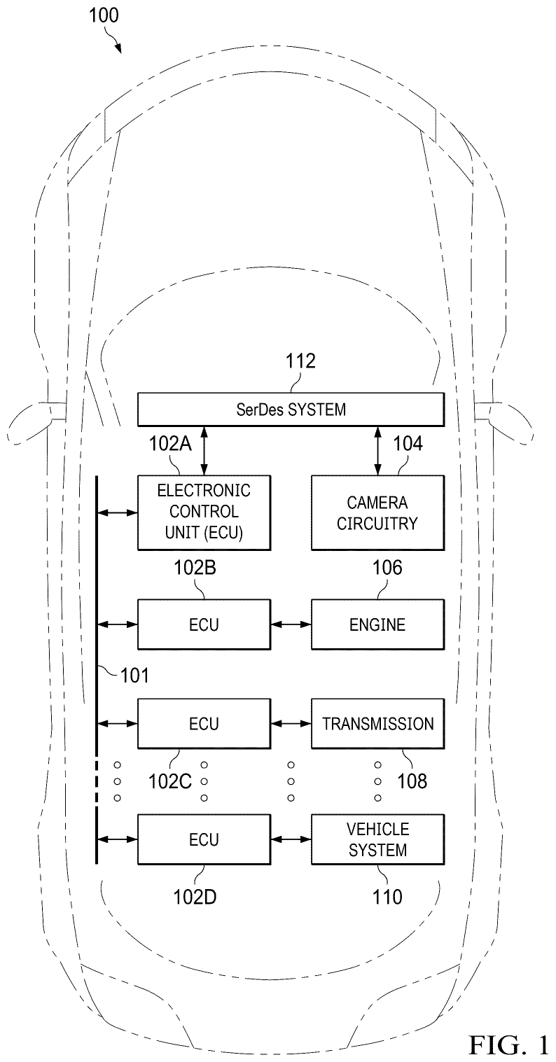

FIG. 1 is a block diagram of an example vehicle 100. The vehicle 100 includes an example bus 101, ECUs 102A, 102B, 102C, 102D (referred to herein as ECUs 102), example camera circuitry 104, an example engine 106, an example transmission 108, an example vehicle system 110, and example Serial Deserializer (SerDes) system 112.

The bus 101 refers to one or more physical connections (e.g., an interconnect, copper trace, etc.) that enables communication between the ECUs 102. The bus 101 may be implemented using one or more communication systems that meet pre-determined threshold power and latency requirements.

The ECUs 102 control a connected system of the vehicle 100. In FIG. 1, the ECU 102A control the camera circuitry 104, the ECU 102B controls the engine 106, . . . , and the ECU 102D controls vehicle system 110. An ECU 102A may control a connected vehicle system responsive to information received from another ECU 102B via the bus 101. For example, suppose the ECU 102B sends rotational speed and/or torque information corresponding to the engine 106 to the ECU 102C. Responsive to the received rotational speed and/or torque information, the ECU 102C may send a signal to the transmission 108 to shift gears. In some examples, the vehicle may contain a different number of ECUs than the system of FIG. 1.

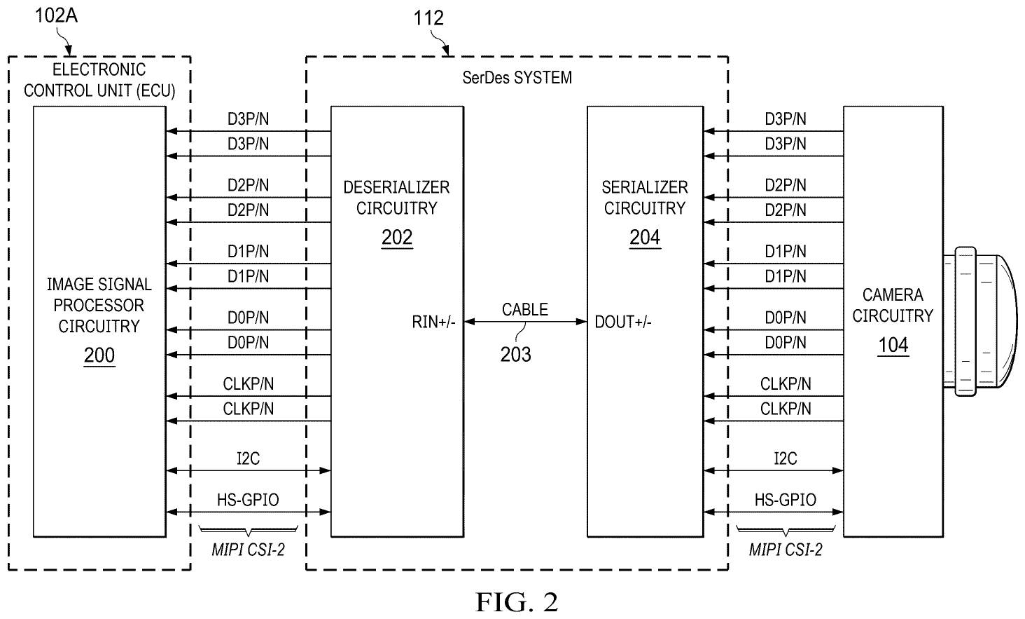

An ECU 102A may also control a connected vehicle system responsive to the exchange of data with the connected vehicle system. The components and protocols used to facilitate communication between an ECU 102D and its corresponding vehicle system 110 may vary responsive to the type of information exchanged, hardware characteristics of the ECU 102D and the vehicle system 110, global requirements of the vehicle 100, etc. In the example of FIG. 1, the ECU 102A and its connected vehicle system (e.g., the camera circuitry 104) communicate with each other using the SerDes system 112. The SerDes system 112 includes a serializer circuitry, deserializer circuitry, and a cable. If the ECU 102A stops receiving images from the camera circuitry 104 at expected intervals, the SerDes system 112 can self-report trouble shooting to the ECU 102A to either report the cable as working properly or describe what faults are present on the cable. The SerDes system 112 is described further in connection with FIG. 2.

FIG. 2 is a block diagram of an example implementation of the SerDes system of FIG. 1. FIG. 2 shows the ECU 102A, the SerDes system 112, and the camera circuitry 104. The ECU 102A includes example Image Signal Processor (ISP) circuitry 200. The SerDes system 112 includes example Deserializer circuitry 202, an example cable 203, and example serializer circuitry 204.

Within the ECU 102A, the ISP circuitry 200 performs operations responsive to images that are captured by the camera circuitry 104. For example, the ISP circuitry 200 may perform color reconstruction, noise reduction, image sharpening, etc. on the image. In some examples, the ISP circuitry 200 may also perform object recognition on images to detect, for example, a pedestrian, another vehicle, or other objects nearby the vehicle 100. The camera circuitry 104 includes any appropriate image sensor used to capture images.

The ISP circuitry 200 and the camera circuitry 104 may communicate with each other using an interface or communication protocol that requires a multitude of channels. In the example of FIG. 2, the channels are labelled according to the Flat Panel Display (FPD) Link video interface and the Mobile Industry Processor Interface (MIPI) Camera Serial Interface 2 (CSI) protocol. In other examples, a different multi-channel communication protocol may be used.

Because the ECU 102A and camera circuitry 104 may be positioned any distance apart from one another, implementing n separate cables across the length of the vehicle 100 to support n channels of communication would add unneeded cost and complexity. Instead, the SerDes system 112 includes only a single channel (e.g., the cable 203) that couples the camera circuitry 104 and the ECU 102A. The SerDes system 112 is full duplex and supports transmission of data in both directions across the cable 203 at the same time.

In the example of FIG. 2, the cable 203 is a coaxial cable. In other examples, the SerDes system 112 implements a different type of cable, including but not limited to Shielded Twisted Pair (STP). In examples above and below, the SerDes system 112 is described in the automative context of FIG. 1. More generally, the SerDes system 112 described herein may be implemented in any application that requires conversion of multiple parallel streams of data into a single serial stream of data for transmission over a high-speed connection, and conversion back the original parallel data at the end destination.

The deserializer circuitry 202 performs the deserializer operations by extracting x different signals generated by the camera circuitry 104 from the analog voltage that travels on the cable 203. After performing deserializer operations, the deserializer circuitry 202 provides the n signals to the ISP circuitry 200 using the same format(s) (e.g., FPD Link and MIPI CSI-2) as the camera circuitry 104. In many examples, the data in the n signals represent images that were captured by the camera circuitry 104.

Forward-channel communications refer to the transmission of primary signals that occur in a first direction between two devices. In examples described herein, data transmitted from the camera circuitry 104 and received by the ISP circuitry 200 are forward-channel communications. In contrast, back-channel communications refer to the transmission of secondary signals that occur in the opposite direction between the two devices. In examples described herein, data transmitted from the ISP circuitry 200 and received by the camera circuitry 104 are back-channel communications.

The deserializer circuitry 202 also performs serializer operations by mapping y signals generated by the ISP circuitry 200 onto an analog voltage for transmission over the cable 203. The information represented in such signals may include instructions to the camera circuitry 104 including but not limited to: when to take an image, what lens or aperture setting to use when taking images, etc. In some examples, the number of signals in forward-channel communications (represented above and herein as x) is different from the number of signals in back-channel communications (represented above and herein as y).

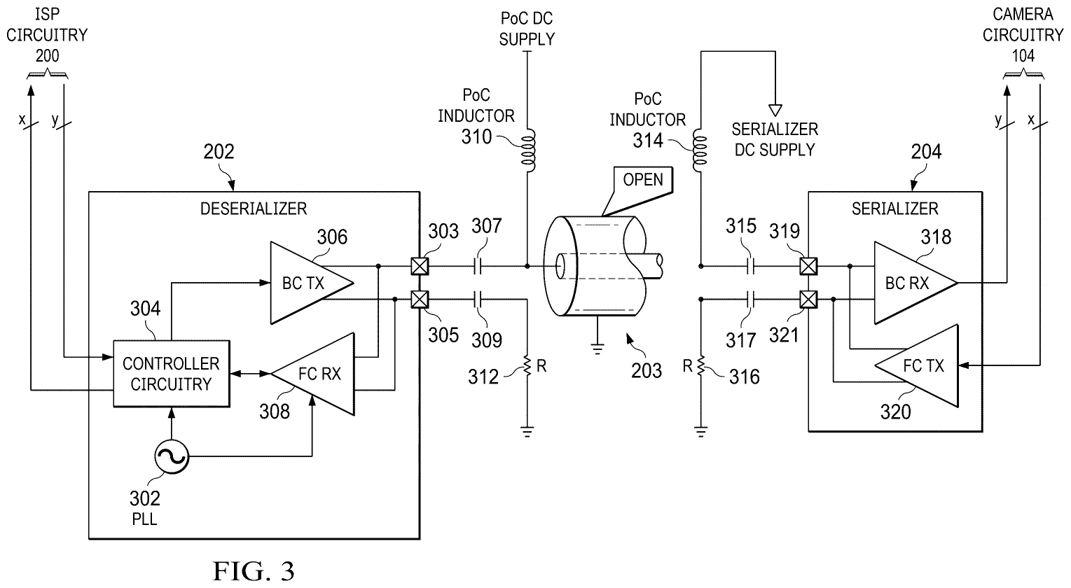

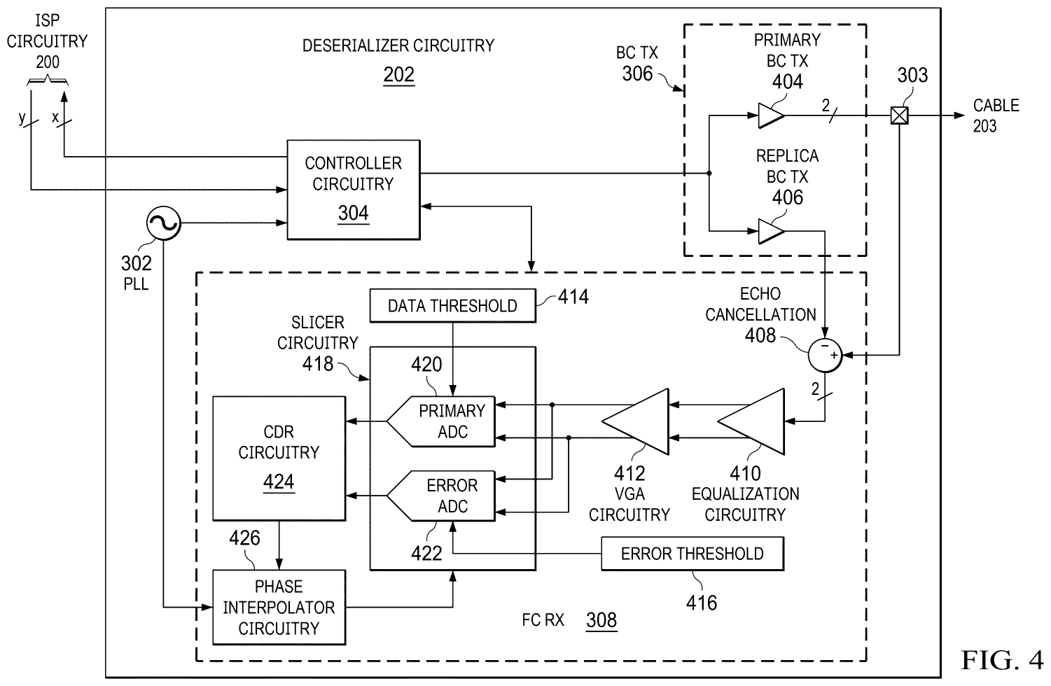

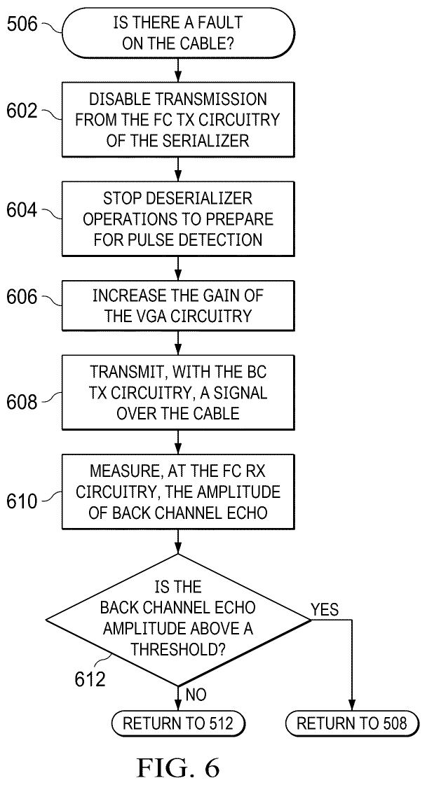

In addition to simultaneously supporting forward-channel and back-channel communications, the deserializer circuitry 202 also performs trouble shooting operations responsive to instructions from the ISP circuitry 200. The ISP circuitry 200 may provide instructions to perform trouble shooting operations for any reason, including but not limited to failure to receive an image at an expected time interval. The deserializer circuitry 202 is described further in connection with FIGS. 3 and 4. In some examples, the deserializer circuitry 202 is instantiated by programmable circuitry executing deserializer instructions to perform operations such as those represented by the flowchart(s) of FIGS. 6, 7, and 9.

The deserializer circuitry 202 of FIG. 2 may be instantiated (e.g., creating an instance of, bring into being for any length of time, materialize, implement, etc.) by one or more threads executing concurrently on hardware or in series on hardware. Also or alternatively, the deserializer circuitry 202 of FIG. 2 may be instantiated (e.g., creating an instance of, bring into being for any length of time, materialize, implement, etc.) by (i) programmable circuitry such as a Central Processor Unit (CPU) executing first instructions, (ii) an Application Specific Integrated Circuit (ASIC) or (iii) a Field Programmable Gate Array (FPGA) structured or configured in response to execution of second instructions to perform operations corresponding to the first instructions. Some or all of the circuitry of FIG. 2 may, thus, be instantiated at the same or different times. Moreover, in some examples, some or all of the circuitry of FIG. 2 may be implemented by microprocessor circuitry executing instructions or FPGA circuitry performing operations to implement one or more virtual machines or containers.

Like the deserializer circuitry 202, the serializer circuitry 204 simultaneously supports both forward-channel and back-channel communications. To support forward-channel communications, the serializer circuitry 204 performs serializer operations by mapping x signals (containing, e.g., image data) generated by the camera circuitry 104 onto an analog voltage for transmission over the cable 203. To support back-channel communications, the serializer circuitry 204 performs deserializer operations by extracting y different signals (containing, e.g., instructions) generated by the ISP circuitry 200 from the analog voltage that travels on the cable 203. Accordingly, the deserializer circuitry 202 and the deserializer circuitry 202 are referred to exclusively by their forward-channel operations despite each circuit also performing back-channel operations.

FIG. 3 is a block diagram of an example implementation of the deserializer circuitry 202 and the serializer circuitry 204 of FIG. 2. FIG. 3 shows the deserializer circuitry 202, which includes example phase locked loop (PLL) circuitry 302, example controller circuitry 304, example terminals 303 and 305, example Back-Channel (BC) Transmitter (TX) circuitry 306, and example Forward-Channel (FC) Receiver (RX) circuitry 308. FIG. 3 also shows the cable 203, example capacitors 307, 309, 315, and 317, inductors 310 and 314, example resistors 312 and 316, and the serializer circuitry 204. The serializer circuitry 204 includes example BC Receiver (RX) circuitry 318, example terminals 319 and 321, and example FC TX circuitry 320.

In the example of FIG. 3, the SerDes system 112 implements Power-over-Coax (PoC). Accordingly, the cable 203 is a coaxial cable that includes both a metal core and a braided metal shield. In other examples, the SerDes system 112 does not implement PoC and the cable 203 is a different type of cable.

The BC TX circuitry 306 has: an input terminal coupled to the controller circuitry 304, a first output terminal coupled to the terminal 303, and a second output terminal coupled to the terminal 305. The FC RX circuitry 308 has a first input terminal coupled to the terminal 303, a second input terminal coupled to the terminal 305, and an output terminal coupled to the controller circuitry 304. The controller circuitry 304 has a first input terminal coupled to the ISP circuitry 200, a second input terminal coupled to the PLL circuitry 302, a third input terminal circuitry coupled to the FC RX circuitry 308, a first output terminal coupled to the ISP circuitry 200, a second output terminal coupled to the BC TX circuitry 306, and a third output terminal coupled to the FC RX circuitry 308.

Within the serializer circuitry 204, the PLL circuitry 302 generates a system level clock signal having the same frequency but a different phase as the incoming analog signal. The PLL circuitry 302 provides the system level clock signal to the controller circuitry 304 and the FC RX circuitry 308. The PLL circuitry 302 may be implemented using any type of programmable circuitry.

The controller circuitry 304 manages the operations of the BC TX circuitry 306 and the FC RX circuitry 308 responsive to instructions from the ISP circuitry 200. For example, the controller circuitry 304 both: a) provides a voltage for the BC TX circuitry 306 to transmit and b) interprets the voltage provided by the FC RX circuitry 308, so that the ISP circuitry 200 can participate in back-channel and forward-channel communications with the camera circuitry 104. In response to the ISP circuitry 200 detecting a fault has occurred, the controller circuitry 304 also uses the BC TX circuitry 306 and the FC RX circuitry 308 to determine: a) whether a fault exists on the cable 203, b) the type of fault that exists on the cable (if any), and c) the location of the fault on the cable (if any). The controller circuitry 304 may be using any type of programmable circuitry. In some examples, the controller circuitry 304 is instantiated by programmable circuitry executing controller instructions to perform operations such as those represented by the flowchart(s) of FIGS. 6, 7, and 9.

The BC TX circuitry 306 transmits a voltage onto a terminal that is coupled to the capacitor 307 and the cable 203. The voltage may represent any type of information sent from the ISP circuitry 200 to the camera circuitry 104. The BC TX circuitry 306 is described further in connection with FIG. 4.

Implementation of PoC requires a separation between power and data through the cable 203. Accordingly, manufacturers and designers of the SerDes System 112 seek to block the DC component of the forward and back-channel communications (e.g., data signals such as FPD-Link) from entering the output pins of the serializer circuitry 204 and the input pins of the deserializer circuitry 202. This is accomplished by the BC TX circuitry 306 transmitting the voltage onto a terminal that is coupled to the capacitor 309 and the resistor 312, thereby blocking the DC component of the signal. In examples where the SerDes system 112 does not implement PoC, the BC TX circuitry 306 may transmit the voltage across a different number of terminals.

The FC RX circuitry 308 receives a voltage on the cable 203 and performs signal processing so that the resulting signal is interpretable by the controller circuitry 304. The voltage may represent any type of information sent from the camera circuitry 104 to the ISP circuitry 200. The FC RX circuitry 308 is coupled to the cable 203 through the same cable interface terminal (referred to herein as terminal 303) as the BC TX circuitry 306. In examples where the SerDes system 112 implements PoC, the FC RX circuitry 308 also shares a second terminal with the BC TX circuitry 306.

As used herein, a normal mode of operations refers to when the deserializer circuitry 202 performs one or more of: transmitting ISP instructions using the BC TX circuitry 306 or receiving image data using the FC RX circuitry 308. If the ISP circuitry 200 stops receiving image data at expected time intervals, the ISP circuitry 200 may instruct the deserializer circuitry 202 to exit the normal mode of operations and enter a troubleshoot mode. Operations performed by the deserializer circuitry 202 during the troubleshoot mode are described further below.

The inductor 310 includes a first terminal coupled to a Direct Current (DC) power supply and a second terminal coupled to the cable 203. The inductor 310 manages the rate of current that flows from the DC power supply and through the cable 203.

The resistor 312 includes a first terminal coupled to the capacitor 309 and a second terminal coupled to ground. The resistor 312 acts as a pull-down resistor to maintain the signal shared by the BC TX circuitry 306 and FC RX circuitry 308 at zero volts when no devices are transmitting.

The inductor 314 includes a first terminal coupled to power regulator circuitry and a second terminal coupled to the cable 203. The inductor 314 manages the rate of current that flows from the power regulator circuitry to the serializer circuitry 204.

When the SerDes system 112 is operating properly, the second terminal of the inductor 314 is also coupled to the cable 203. However, in the example of FIG. 3, the cable 203 has an open circuit (e.g., a fault). The fault breaks the coupling between the cable 203 and the inductor 314. More generally, the fault also breaks the coupling between the deserializer circuitry 202 and the serializer circuitry 204. As a result, the SerDes system 112 may cause unexpected behavior (e.g., the failure to provide the ISP circuitry 200 an image at an expected time) due to the fault on the cable 203.

The example of cable 203 shows the cable 203 as a collection of one or more wires implemented outside of an IC. In other examples, the cable 203 may be implemented using one or more interconnects and vias within an IC.

The resistor 316 includes a first terminal coupled to the capacitor 317 and a second terminal coupled to ground. The resistor 316 acts as a pull-down resistor to maintain the signal shared by the BC RX circuitry 318 and FC TX circuitry 320 at zero volts when no devices are transmitting. Moreover, because the SerDes system 112 is fully differential in nature, the resistors 312 and 316 emulate far end termination in a single ended system. For example, a replica transmitter device within the BC TX circuitry 308 has an internal termination on both positive and negative terminals. Accordingly, the resistors 312 and 316 help reduce mismatch between the replica and main path, thereby reducing echo in transmitted signals. Replica transmitter circuitry is described further in connection with FIG. 4.

In examples where the SerDes system 112 does not exhibit a fault, the BC RX circuitry 318 within the serializer circuitry 204 receives a voltage on the cable 203 that is transmitted by the BC TX circuitry 306. As described above, the BC RX circuitry 318 extracts y signals from the voltage to properly format the ISP instructions in a manner interpretable by the camera circuitry 104.

Similarly, the FC TX circuitry 320 transmits a single voltage over the cable 203 responsive to the x signals generated by the camera circuitry 104. Like the deserializer circuitry, the BC RX circuitry 318 and the FC TX circuitry 320 may be coupled to the cable 203 through a shared terminal.

Because the SerDes system 112 uses a single transmission medium (e.g., the cable 203) to simultaneously support bi-directional channel communications, part of the voltage at measured at the FC RX circuitry 308 may be inadvertently contributed by the BC TX circuitry 306. Such voltage is referred to in examples herein as an echo or a reflection because it represents a portion of an outgoing signal that has reappeared in an incoming signal.

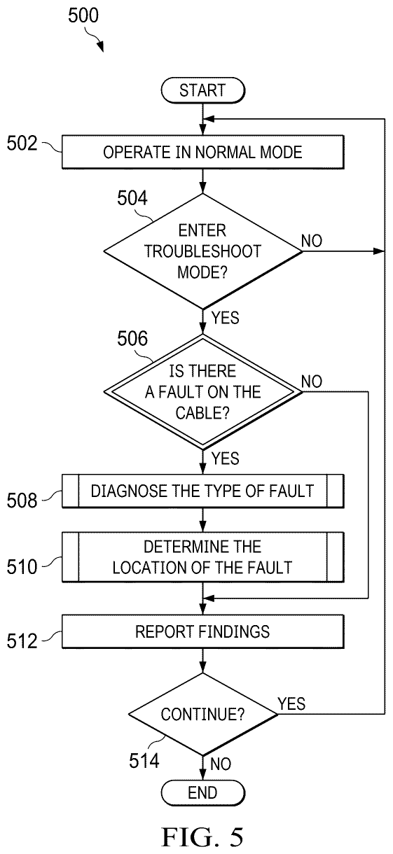

The FC RX circuitry 308 removes echoes that occur at the terminal 303 during normal operations. Notably, the presence of a fault on the cable 203 can also create echoes or change the characteristics of preexisting echoes. Accordingly, the controller circuitry 304 troubleshoots the existence, type, and location of faults by: a) stopping normal operations between the ISP circuitry 200 and camera circuitry 104, b) transmitting a test signal over the cable with the BC TX circuitry 306, and c) measuring the echoes that are received at the FC RX circuitry 308. The types of test signals sent over the cable 203 and the type of measurements performed on the signal obtained at the FC RX circuitry 308 are described further in connection with FIGS. 5-9.

In the example of FIG. 2, the deserializer circuitry 202 performs operations to troubleshoot the cable because the serializer circuitry 204 does not include control circuitry. A manufacturer or designer may choose to implement the SerDes system 112 as shown in FIG. 2 to implement the logic from the controller circuitry 304 and the logic from the ISP circuitry 200 physically near each other (e.g., as two SoCs on a shared motherboard). In other examples, the serializer circuitry 204 implements control circuitry rather than the deserializer circuitry 202. In such instances, the serializer circuitry 204 performs operations to troubleshoot the cable as described in the examples herein.

FIG. 4 is a block diagram of an example implementation of the deserializer circuitry of FIG. 2. The deserializer circuitry 202 includes the PLL circuitry 302, the controller circuitry 304, the BC TX circuitry 306, and the FC RX circuitry 308. The BC TX circuitry 306 includes example primary BC TX circuitry 404 and example replica BC TX circuitry 406. The FC RX circuitry 308 includes example echo cancellation circuitry 408, example equalization circuitry 410, example Variable Gain Amplifier (VGA) circuitry 412, an example data threshold voltage 414, an example error threshold voltage 416, example slicer circuitry 418, example Clock and Data Recovery (CDR) circuitry 424, and example phase interpolator (PI) circuitry 426. The slicer circuitry 418 includes example primary Analog to Digital Converter (ADC) circuitry 420 and example error ADC circuitry 422.

During normal operations, the controller circuitry 304 supports bi-directional communication by adapting a feedback loop between the PLL circuitry 302, the BC TX circuitry 306, and the FC RX circuitry 308. The adaptation of the feedback loop is described further below in connection with FIG. 4. The controller circuitry 304 also implements a troubleshoot mode as described further in connection with FIGS. 5-9.

In some examples, the deserializer circuitry 202 includes frequency divider circuitry that obtains an input signal from the PLL circuitry 302 and provides an output signal and to the controller circuitry 304, where the output signal has a lower frequency than the input signal. The deserializer circuitry 202 may include the frequency divider circuitry in examples where the bi-directional communication is asynchronous (e.g., ISP instructions travelling on back-channel communications are transmitted at a different frequency than image data travelling on front-channel communications). The frequency divider circuitry may also be referred to as an n-divider, a clock divider, a scaler, or a pre-scaler circuit.

The primary BC TX circuitry 404 performs amplitude control operations to transform the digital signal provided by the controller circuitry 304 into an analog signal. The primary BC TX circuitry 404 then transmits the resulting output over the cable 203 via the terminal 303. The primary BC TX circuitry 404 may also perform operations to control the slew rate of the outgoing signal. During normal operations, the output of the primary BC TX circuitry 404 may include ISP instructions as described above.

The replica BC TX circuitry 406 also performs amplitude control operations to transform the digital signal provided by the controller circuitry 304 into an analog signal. The replica BC TX circuitry 406 then provides the output signal to the echo cancellation circuitry 408 within the FC RX circuitry 308. During normal operations, the output of the replica BC TX circuitry 406 includes the same ISP instructions output as the primary BC TX circuitry 404.

The echo cancellation circuitry 408 receives a first voltage from the replica BC TX circuitry 406 and a second voltage from the terminal 303. The value of the voltage received from the terminal 303 is representative of both: a) the outgoing signal produced by the primary BC TX circuitry 404 and b) other signals that arrived at the terminal 303 via the cable 203. In contrast, the output signal provided by the replica BC TX circuitry 406 is unaffected by other signals that may be present on the cable 203.

During normal operations, the echo cancellation circuitry 408 uses the output of the replica BC TX circuitry 406 to identify an echo in the signal obtained via the cable 203. The echo cancellation circuitry 408 then removes the echo from the cable signal such that the remaining voltage is only representative of forward-channel communications (e.g., image data).

The equalization circuitry 410 equalizes the differential signal it receives from the echo cancellation circuitry 408. To equalize the signal, the equalization circuitry 410 applies a linear filter that attenuates low-frequency signal components, amplifies components up to the Nyquist frequency, and reduces the magnitude of higher frequencies. The equalization circuitry 410 performs operations responsive to an equalization (EQ) parameter determined by the controller circuitry 304. The operations performed by the controller circuitry 304 to find an optimal EQ setting may be referred to as Adaptive Equalization (AEQ). The controller circuitry 304 may use any suitable equalization technique to find an appropriate equalization setting.

The VGA circuitry 412 amplifies the signal it receives from the equalization circuitry 410 by increasing the amplitude of the signal. The ratio between the output signal amplitude and the input signal amplitude of the VGA circuitry 412 is referred to as the gain of the VGA circuitry 412. The VGA circuitry 412 can amplify signals at any gain within a range of continuous values (or within a group of discrete values) that the component is rated to support. In the example of FIG. 2, the specific gain value used by the VGA circuitry 412 is selected by the controller circuitry 304.

Within the slicer circuitry 418, the primary ADC circuitry 420 samples the differential signal responsive to timing data provided by the phase interpolator circuitry 426. The primary ADC circuitry 420 then produces digital values responsive to a comparison of: a) the difference between the positive and negative portions of the differential signal, and b) the data threshold voltage 414. When the difference between the portions of the differential signal is greater than the data threshold voltage 414, the primary ADC circuitry 420 outputs a first logical state (e.g., a one). Alternatively, when the difference between portions of the differential signal is less than the data threshold voltage 414, the primary ADC circuitry 420 generates a different logical state (e.g., a zero). The controller circuitry 304 provides the data threshold voltage 414 to the primary ADC circuitry 420. The controller circuitry 304 also changes the value of the data threshold voltage 414 responsive to which mode the deserializer circuitry 202 is currently operating in.

The error ADC circuitry 422 operates similarly to the primary ADC circuitry 420 but uses a different threshold voltage. For example, the error ADC circuitry 422 samples the differential signal responsive to timing data provided by the phase interpolator circuitry 426. The error ADC circuitry 422 also produces digital values responsive to a comparison of: a) the difference between the positive and negative portions of the differential signal, and b) the error threshold voltage 416. When the difference between the portions of the differential signal is greater than the error threshold voltage 416, the primary ADC circuitry 420 outputs a first logical state (e.g., a one). Alternatively, when the difference between portions of the differential signal is less than the error threshold voltage 416, the error ADC circuitry 422 generates a different logical state (e.g., a zero). The controller circuitry 304 provides the error threshold voltage 416 to the error ADC circuitry 422. The controller circuitry 304 also changes the value of the error threshold voltage 416 responsive to which mode the deserializer circuitry 202 is currently operating in.

During normal operation, the controller circuitry 304 sets the data threshold voltage 414 and the error threshold voltage 416 so that the slicer circuitry 418 performs Decision Feedback Equalization (DFE) operations. During DFE operations, the controller circuitry 304 keeps the data threshold voltage 414 constant while changing the error threshold voltage 416 until the error ADC circuitry 422 starts to produce a different digital value than the primary ADC circuitry 420. The value of the error threshold voltage 416 that causes the digital outputs to be different also characterizes where the error ADC circuitry 422 is no longer sampling the analog differential signal accurately. The controller circuitry 304 then uses the value of the error threshold voltage 416 to adjust one or more of the echo cancellation circuitry 408, the equalization circuitry 410, or the VGA circuitry 412, thereby adapting the feedback loop shown in FIG. 4.

The CDR circuitry 424 determines when the primary ADC circuitry 420 and error ADC circuitry 422 are to sample the analog differential signals. The CDR circuitry 424 selects a sampling time that is at or near the peak of a logical value, thereby increasing the accuracy of the ADC circuits. In doing so, the CDR circuitry 424 improves clock and data synchronization by reducing timing uncertainty between the deserializer circuitry 202 and the serializer circuitry 204. In some examples, the CDR circuitry 424 mitigates jitter, a form of noise in the analog differential signal. The CDR circuitry 424 may be implemented using any type of programmable circuitry and any type of recovery technique.

The CDR circuitry 424 provides instructions to the PI circuitry 426 describing when the analog input signals are to be sampled. The PI circuitry 426 also receives a system level clock signal from the PLL circuitry 302. The system level clock signal has the same frequency but different phase as the incoming analog signal. The PI circuitry 426 produces control signals that includes a specific amount of delay (e.g., a phase shift) relative to the clock signal provided by the PLL circuitry 302. The primary ADC circuitry 420 and error ADC circuitry 422 sample the data responsive to the control signals. Accordingly, the delay introduced by the PI circuitry 426 implements the desired sampling time set by the CDR circuitry 424. The PI circuitry 426 may be implemented using any type of programmable circuitry and any type of phase interpolation technique.

In examples described herein, the controller circuitry 304 uses the components of the BC TX circuitry 306 and FC RX circuitry 308 for more than one purpose. During normal operation, the BC TX circuitry 306 and FC RX circuitry 308 support bi-directional communications by enabling an adaptive feedback loop and performing DFE operations as described above. During troubleshoot mode, the controller circuitry 304 then uses the BC TX circuitry 306 and FC RX circuitry 308 to support determinations of: whether a fault exists on the cable, what type of fault exists on the cable, and where a fault is located on the cable. The techniques used by the controller circuitry 304 to repurpose the BC TX circuitry 306 and the FC RX circuitry 308 are described further in connection with FIGS. 5-9.

FIG. 5 is a flowchart representative of example machine-readable instructions or example operations that may be at least one of executed, instantiated, or performed using an example programmable circuitry implementation of the controller circuitry of FIG. 3. The example machine-readable instructions and/or the example operations 500 of FIG. 5 begin when the controller circuitry 304 operates the deserializer circuitry 202 in normal mode. (Block 502). Normal mode refers to the use of back-channel communications to transmit ISP instructions and the use of forward-channel communications to receive image data as described above. To support such data exchange between the ISP circuitry 200 and the camera circuitry 104, the controller circuitry 304 adapts parameters of the FC RX circuitry 308 to continue echo cancellation, equalization, phase interpolation, and frequency adjustment operations responsive to changes to data and noise levels within the signal at the terminal 303.

The controller circuitry 304 determines whether to enter troubleshoot mode. (Block 504). In some examples, the controller circuitry 304 enters troubleshoot mode in response to instructions to do so from the ISP circuitry 200. In other examples, the controller circuitry 304 decides to enter test mode itself without instructions from an external device. The ISP circuitry 200 may instruct the deserializer circuitry 202 to enter troubleshoot mode for any reason, including but not limited to: unexpected behavior such as not receiving image data at an expected time, the passage of a predetermined amount of time since the last check for faults, etc.

If the deserializer circuitry 202 does not enter troubleshoot mode (Block 504: No), control returns to block 502 where the controller circuitry 304 continues operations in normal mode. Alternatively, if the deserializer circuitry 202 does enter troubleshoot mode (Block 504: Yes), the controller circuitry 304 determines whether there a fault exists on the cable. (Block 506). Block 506 is described further in connection with FIG. 6.

If the controller circuitry 304 determines a fault does not exist on the cable (Block 506: No), control proceeds to block 512. Alternatively, if the controller circuitry 304 determines a fault does exist on the cable 203 (Block 506: Yes), the controller circuitry 304 then determines the type of fault. (Block 508). The fault on the cable 203 may be an open circuit or a closed circuit. An open circuit may refer to any condition that prevents the flow of current across the cable. Examples of open circuits include but are not limited to a mechanical failure that snaps some or all of the cable 203 as illustrated in FIG. 3.

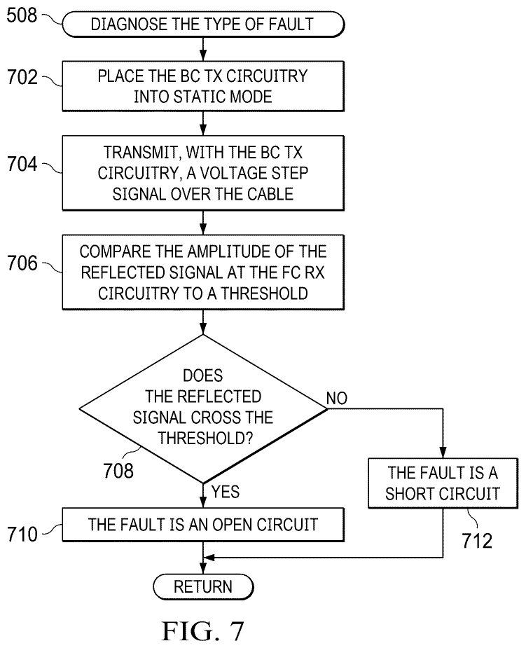

The controller circuitry 304 determines the location of the fault. (Block 510). The fault may be located in any position along the length of the cable 203. In some examples, the cable 203 experiences multiple simultaneous faults. Accordingly, in some examples, the SerDes system 112 includes deserializer circuitry 202 and serializer circuitry 204 that are both capable of implementing the machine-readable instructions and/or operations 500. If both devices implement the flowchart of FIG. 5, then the SerDes system 112 can collectively report: a) the location of a first fault that is closer to the deserializer circuitry 202, and b) the location of a different fault that is closer to the serializer circuitry 204. Block 510 is described further in connection with FIG. 7.

The controller circuitry 304 reports its findings. (Block 512). In some examples, a the findings include a report that the cable 203 is not currently exhibiting a fault (e.g., Block 506: No). In other examples, the findings indicate there is a fault currently on the cable 203, describe the fault as one of an open circuit or short circuit, and describe the location of the fault.

In the example of FIG. 2, the controller circuitry 304 reports its findings to the ISP circuitry 200. In other examples, the controller circuitry 304 reports its findings to a different external device. The external device may perform any type of preventative actions in response to receiving the findings of at 510. For example, the ISP circuitry 200 may, by communicating with one or more systems in the vehicle 100 responsive to a determination the cable 203 does have a fault: disable, enter a safety mode, or otherwise change one or more ADAS capabilities, provide notice to a user of the vehicle 100 regarding which portions of the cable 203, if any, need to be repaired or replaced, etc.

The controller circuitry 304 determines if the deserializer circuitry 202 will continue performing operations. (Block 514). The controller circuitry 304 may continue performing operations whenever the deserializer circuitry 202 (and more generally, the SerDes system 112) is powered ON. A manufacturer or designer of the vehicle 100 may choose to power the SerDes system 112 at any time and for any reason. In some examples, the SerDes system 112 is powered ON whenever the vehicle 100 is running, while in other examples, the SerDes system 112 remained powered OFF unless the vehicle 100 during usage periods that do not rely on the camera circuitry 104.

If the controller circuitry 304 determines to continue (Block 514: Yes), control returns to block 502 where the deserializer circuitry 202 continues in normal mode. If the controller circuitry 304 does not continue (Block 514: No), the machine-readable instructions and/or operations end.

As described further in FIGS. 6, 7, and 9, implementation of blocks 506, 508, and 510 each include a form of: a) transmitting, with the BC TX circuitry 306, a signal across the cable 203, and b) measuring a corresponding reflected signal with the FC RX circuitry 308. In the example of FIG. 5, the controller circuitry 304 performs three separate transmissions to implement blocks 506, 508, and 510 separately from one another. The separate transmissions occur because the hardware used to perform normal operations (e.g., at block 504) has loop latency that prevents the controller performing blocks 506-510 with a single transmission. In other examples, the deserializer circuitry 202 is implemented normal mode and troubleshoot mode using separate hardware components. In such other examples, the controller circuitry 304 may implement all of blocks 506-510 with a single transmission across the cable 203.

FIG. 6 is a flowchart representative of example machine-readable instructions or example operations that may be at least one of executed, instantiated, or performed to determine if a fault exists as described in FIG. 5. In particular, FIG. 6 is an example implementation of block 506 of FIG. 5.

Execution of block 506 begins when the controller circuitry disables transmission from the FC TX circuitry 320 of the serializer circuitry 204. (Block 602). To do so, the controller circuitry 304 causes the BC TX circuitry 306 to send a message over the cable 203. The message instructs the serializer circuitry 204 to stop further transmissions. The stop of forward-channel transmissions at block 602 marks the exit of normal mode (e.g., the operations performed at block 502) and the beginning of troubleshoot mode. In some examples, the state of the serializer circuitry 204 when it is prevented from transmitting on the forward-channel may be referred to as reset mode.

The controller circuitry 304 has not yet determined whether a fault is present at block 602. If the cable 203 does not have a fault, then the BC RX circuitry 318 successfully receives the message from the BC TX circuitry 306, and, in response, the serializer stops forward-channel communications. If the cable 203 does have a fault, the fault may prevent the BC RX circuitry 318 from receiving the message containing instructions. However, in such examples, the same fault would also prevent the FC TX circuitry 320 from successfully transmitting data across the cable 203. Accordingly, the operations performed at block 602 ensure that the voltage ats the terminal 303 of the deserializer circuitry 202 does not include any transmissions from the FC TX circuitry 320, regardless of whether the cable 203 has a fault.

The controller circuitry 304 stops certain deserializer operations for pulse detection. (Block 604). For example, the controller circuitry 304 freezes the phase interpolator circuitry 426 because the changes to ADC timing produced by the phase interpolator circuitry 426 are designed for normal mode operations. If the phase interpolator circuitry 426 was left powered on, the ADCs in the slicer circuitry 418 may inadvertently sample the voltage from the terminal 303 at the wrong time and miss the reflected signal. Similarly, the controller circuitry 304 stops the DFE operations at block 604 because the loop adaptation described above is designed for normal mode operations.

The controller circuitry 304 also sets the equalization circuitry 410 to a zero EQ setting and turns off the echo cancellation circuitry 408 at block 604. The zero EQ setting prevents the equalization circuitry 410 from performing equalization operations that would alter the shape of the reflected signal. Finally, the controller circuitry 304 sets the BC TX circuitry 306 in a common mode at block 604. The common mode stops the BC TX circuitry 306 from performing normal mode operations (e.g., transmitting ISP instructions).

When the FC RX circuitry 308 measures the voltage at the terminal 303, reflected signals received are small in magnitude compared to signals that are transmitted by the FC TX circuitry 320. Accordingly, during normal mode, the controller circuitry 304 may set the VGA circuitry 412 to a comparatively small value to assist in both: a) detecting the intentionally transmitted signals and b) ignoring the unintentional reflected signals. During troubleshoot mode, however, the controller circuitry 304 sets the VGA circuitry 412 to an increased gain value. (Block 606). The increased gain of the VGA circuitry 412 increases the amplitude of the reflected signal as much as possible, thereby ensuring the reflected signal can be detected through comparison to threshold voltages at the slicer circuitry 418.

The controller circuitry 304 causes the BC TX circuitry 306 to transmit a signal over the cable. (Block 608). In the example of FIG. 6, the BC TX circuitry 306 transmits a voltage corresponding to one bit of information. In other examples, the BC TX circuitry 306 transmits a different type of signal.

The FC RX circuitry 308 measures the amplitude of the echo caused by the back-channel transmission. (Block 610). The back-channel echo voltage is measurable at the FC RX circuitry 308 because the SerDes system 112 is full duplex. As a result, the cable 203 is coupled to both the BC TX circuitry 306 and the FC RX circuitry 308 via the terminal 303.

The amplitude of the back-channel echo is responsive to the presence of a fault on the cable 203. Accordingly, the controller circuitry 304 determines whether the back-channel echo amplitude is above a threshold. (Block 612). The threshold of block 612 is a voltage pre-determined by the controller circuitry 304 and provided to the FC RX circuitry 308 as one or more of the data threshold voltage 414 and the error threshold voltage 416. Accordingly, the controller circuitry 304 may set the data threshold voltage 414 and the error threshold voltage 416 to first values during normal operations, then change one or more of the thresholds to different values to perform block 608. The values of the data threshold voltage 414 and the error threshold voltage 416 influence which digital values are produced by the slicer circuitry 418 as described above.

If the amplitude of the echo is less than the threshold voltage (Block 612: No), then the cable 203 successfully reached the serializer circuitry 204 because both termination resistors 312 and 316 reduce the magnitude of the echo, thereby causing the FC RX circuitry 308 to measure a comparatively small value. Accordingly, in such examples, the cable 203 does not have a fault and control proceeds to block 512 of FIG. 5.

Alternatively, if the amplitude of the echo is larger than the threshold voltage (Block 612: Yes), then the signal did not reach the serializer circuitry 204 because the comparatively large measurement value implies the termination resistor 316 did not reduce the magnitude of the echo. Accordingly, in such examples, the cable 203 does have a fault and control proceeds to block 508 of FIG. 5.

FIG. 7 is a flowchart representative of example machine-readable instructions or example operations that may be at least one of executed, instantiated, or performed to diagnose a type of fault as described in FIG. 5. In particular, the flowchart of FIG. 7 is an example implementation of block 508 of FIG. 5.

Execution of block 508 begins when the controller circuitry 304 places the BC TX circuitry 306 into static mode. (Block 702). As used above and herein, static mode refers to when the controller circuitry 304 instructs the BC TX circuitry 306 to continuously transmit the same voltage value. The static voltage value may be any voltage supported by the BC TX circuitry 306. In some examples, static mode may be alternatively referred to as common mode. Notably, the controller circuitry 304 has already stopped deserializer operations (block 904) and increased the gain of the VGA circuitry 412 (block 606) before execution of block 702, so re-executing such blocks in FIG. 7 is not necessary.

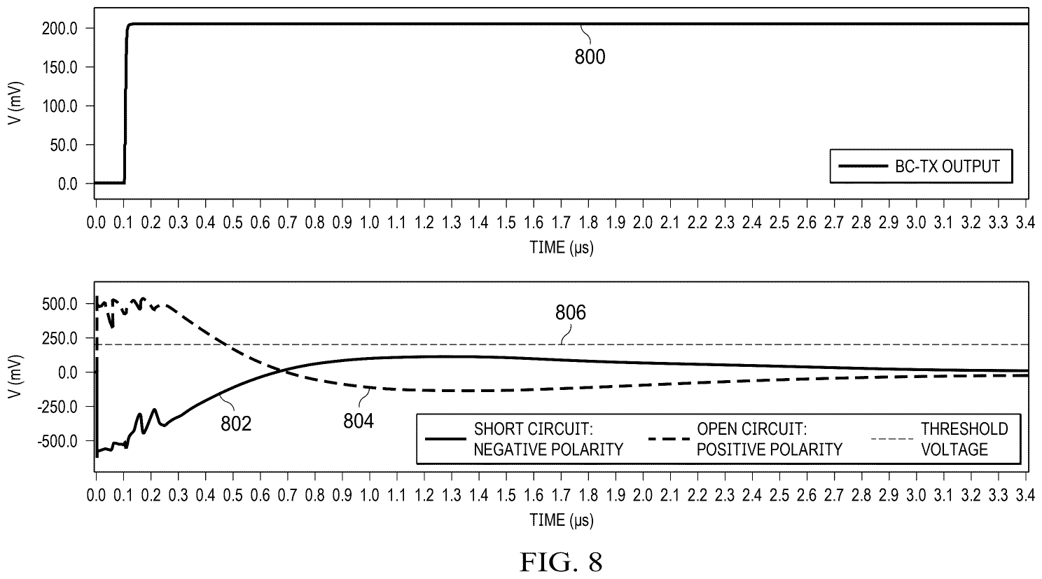

The controller circuitry 304 transmits, with the BC TX circuitry 306, a voltage step signal over the cable 203. (Block 704). To do so, the controller circuitry 304 first sets the static voltage of the BC TX circuitry 306 to a low supply voltage, then changes the static voltage to a high supply voltage. In some examples, the change between the high and low supply voltages is referred to as a change in the polarity of the static mode. An example of the voltage step signal is shown in FIG. 8.

When the transmitted voltage step signal reaches the fault on the cable 203, some or all of the signal reflects at the fault and travels backwards towards the deserializer circuitry 202. The polarity of the reflected voltage step signal is responsive to the type of fault on the cable 203. The controller circuitry 304 determines the polarity by comparing the amplitude of the reflected signal, as measured at the FC RX circuitry 308, to a threshold. (Block 706). The threshold of block 808 is a voltage pre-determined by the controller circuitry 304 and provided to the FC RX circuitry 308 as one or more of the data threshold voltage 414 and the error threshold voltage 416. The controller circuitry 304 may use different threshold voltage values at block 706 than the threshold voltage values used when performing normal operations (e.g., at block 502) or when determining whether the fault exists (e.g., at block 606). An example of the threshold value of block 706 is shown in FIG. 8.

The controller circuitry 304 determines whether the reflected signal crosses the threshold. (Block 708). The reflected signal crosses the reflected signal if, during a measurement window, the amplitude of the reflected signal transitions from greater than the threshold to less than the threshold (or vice versa). If the reflected signal does cross the threshold (Block 708: Yes), the fault on the cable 203 is an open circuit. (Block 710). Alternatively, if the reflected signal does not cross the threshold (Block 708: No), the fault on the cable 203 is a short circuit. (Block 712). The machine-readable instructions or operations 500 return to block 510 after either block 710 or block 712.

FIG. 8 is a graph showing example outputs of the VGA circuitry 412 as described in connection with FIG. 7. FIG. 8 includes example signals 800, 802, 804, and an example threshold voltage 806. The signals 802-804 and the threshold voltage 806 are plotted on two graphs. Both graphs have time on the x axis, measured in microseconds (us), and voltage on the y axis, measured in millivolts (mV). The x axes from the two graphs refer to the same points in time.

The signal 800 is an example implementation on the voltage step signal used to detect the type of fault. The primary BC TX circuitry 404 and the replica BC TX circuitry 406 generate the step signal 800 at block 704 of FIG. 7 responsive to instructions from the controller circuitry 304. In the example of FIG. 8, the step signal 800 includes a transition from 0 V to 200 mV. In other examples, the step signal includes a transition from one or more different voltage levels.

In some examples, the step signal reflects off a short circuit on the cable 203 and returns to the deserializer circuitry 202. In such examples, the reflected signal has a negative polarity as displayed in FIG. 8 with the signal 802. The signal 802 shows that short circuit faults cause the magnitude of the reflected signal to initially decrease and then gradually increase over time. Notably, the signal 802 never crosses the threshold voltage 806. Accordingly, if the FC RX circuitry 308 receives the signal 802, the controller circuitry 304 can use the threshold voltage 806 at blocks 706 and 708 of FIG. 7 to diagnose the type of fault as a short circuit.

In other examples, the step signal reflects off an open circuit on the cable 203 and returns to the deserializer circuitry 202. In such examples, the reflected signal has a positive polarity as displayed in FIG. 8 with the signal 804. The signal 804 shows that open circuit faults cause the magnitude of the reflected signal to initially increase and then gradually decrease over time. Notably, the signal 802 does cross the threshold voltage 806. Accordingly, if the FC RX circuitry 308 receives the signal 804, the controller circuitry 304 can use the threshold voltage 806 at blocks 706 and 708 of FIG. 7 to diagnose the type of fault as an open circuit.

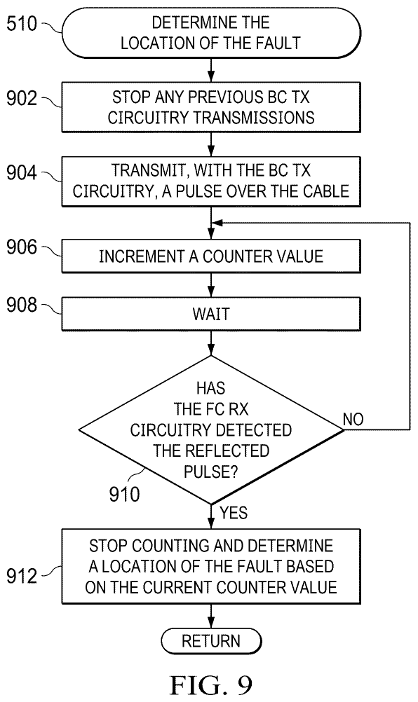

FIG. 9 is a flowchart representative of example machine-readable instructions or example operations that may be at least one of executed, instantiated, or performed to determine a location of a fault as described in FIG. 5. In particular, the flowchart of FIG. 9 is an example implementation of block 510 of FIG. 5.

Execution of block 510 begins when the controller circuitry 304 stops any previous transmissions from the BC TX circuitry 306. (Block 902). Notably, the controller circuitry 304 has already stopped deserializer operations (block 604) and increased the gain of the VGA circuitry 412 (block 606) before execution of block 902 so re-executing such blocks in FIG. 9 is not necessary. After confirming that any previous transmissions have stopped, the controller circuitry 304 then transmits, with the BC TX circuitry 306, a voltage pulse over the cable 203. (Block 904). The voltage pulse includes a first transition from one logical state to another, followed by a second transition back to the original logical state. The voltage pulse may extend for any period of time.

The controller circuitry 304 increments a counter value (Block 906) and waits an amount of time (Block 908) before determining whether the FC RX circuitry 308 has detected the reflected pulse. (Block 910). The controller circuitry 304 determines the reflected pulse has been detected by providing values of the data threshold voltage 414 and error threshold voltage 416 such that the value of the digital values produced by the slicer circuitry 418 change responsive to whether the reflected pulse has arrived within the signal chain.

If the controller circuitry 304 determines the FC RX circuitry 308 has not yet detected the reflected pulse (Block 910: No), control returns to block 908 where the controller circuitry 304 increments the counter again. The controller circuitry 304 may implement the loop of blocks 906-910 using any technique that measures the passage of time since the pulse was initially transmitted at block 906. For example, the controller circuitry 304 may increment the counter each time n pulses occur in a clock signal, where n is any positive integer.

If the FC RX circuitry 308 has detected the reflected pulse (Block 910: Yes), the controller circuitry 304 stops counting and determines a location of the current counter value. (Block 912). For example, the controller circuitry 304 may first convert the counter value into an amount of time that has passed between: a) transmitting the pulse at block 904 and b) detecting the reflected version of the pulse at block 910. The amount of time represents the round-trip journey for a signal that started at the deserializer circuitry, reflected at the fault, ended back at the deserializer circuitry 202. Accordingly, the controller circuitry 304 determines half the round-trip value (e.g., divides the value by two) to obtain the amount of time it took for the pulse to travel from the BC TX circuitry 306 to the fault on the cable 203. Finally, the controller circuitry 304 converts the one-way time measurement to a distance responsive to the propagation delay of the cable 203. The resulting value is the distance between the deserializer circuitry 202 and the fault. The machine-readable instructions or operations 500 return to block 512 after block 912.

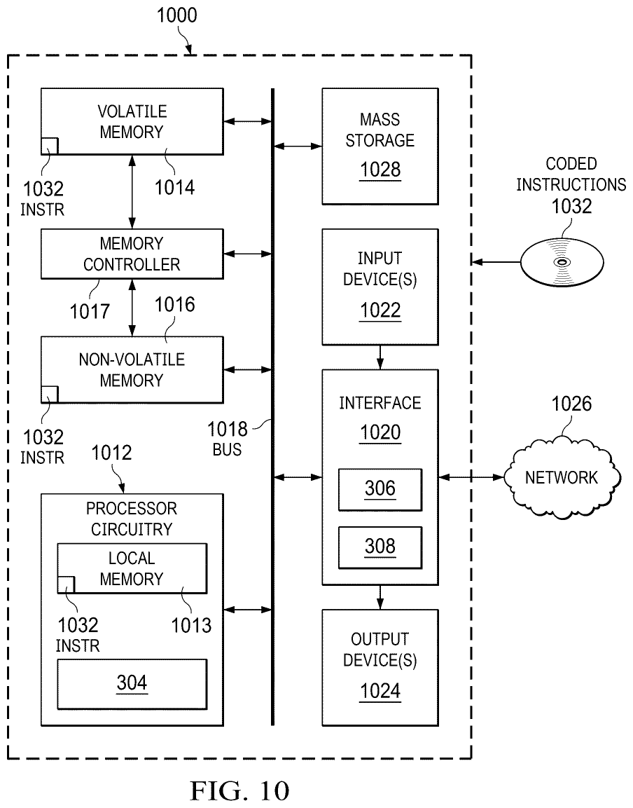

FIG. 10 is a block diagram of an example programmable circuitry platform 1000 structured to one or a combination of execute or instantiate one or more of the example machine-readable instructions or the example operations of FIGS. 6, 7, and 9 to implement the deserializer circuitry 202 of FIGS. 3 and 4. In the examples described above, the programmable circuitry platform 1000 is implemented within a vehicle 100 that includes camera circuitry 104. More generally, the programmable circuitry platform 1000 may be implemented wherever a SerDes system is used. Such applications may include, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing or electronic device.

The programmable circuitry platform 1000 of the illustrated example includes programmable circuitry 1012. The programmable circuitry 1012 of the illustrated example is hardware. For example, the programmable circuitry 1012 can be implemented by one or more integrated circuits, logic circuits, FPGAs, microprocessors, CPUs, GPUs, DSPs, or microcontrollers from any desired family or manufacturer. The programmable circuitry 1012 may be implemented by one or more semiconductor based (e.g., silicon based) devices. In this example, the programmable circuitry 1012 implements the controller circuitry 304.

The programmable circuitry 1012 of the illustrated example includes a local memory 1013 (e.g., a cache, registers, etc.). The programmable circuitry 1012 of the illustrated example is in communication with main memory 1014, 1016, which includes a volatile memory 1014 and a non-volatile memory 1016, by a bus 1018. The volatile memory 1014 may be implemented by one or more Synchronous Dynamic Random Access Memory (SDRAM), Dynamic Random Access Memory (DRAM), RAMBUS® Dynamic Random Access Memory (RDRAM®), or any other type of RAM device. The non-volatile memory 1016 may be implemented by one or a combination of flash memory or any other desired type of memory device. Access to the main memory 1014, 1016 of the illustrated example is controlled by a memory controller 1017. In some examples, the memory controller 1017 may be implemented by one or more integrated circuits, logic circuits, microcontrollers from any desired family or manufacturer, or any other type of circuitry to manage the flow of data going to and from the main memory 1014, 1016.

The programmable circuitry platform 1000 of the illustrated example also includes interface circuitry 1020. The interface circuitry 1020 may be implemented by hardware in according to any type of interface standard, such as an Ethernet interface, a universal serial bus (USB) interface, a Bluetooth® interface, a near field communication (NFC) interface, a Peripheral Component Interconnect (PCI) interface, or a Peripheral Component Interconnect Express (PCIe) interface. In this example, the interface circuitry 1020 includes the BC TX circuitry 306 and the FC RX circuitry 308.

In the illustrated example, one or more input devices 1022 are connected to the interface circuitry 1020. The input device(s) 1022 permit(s) a user (e.g., a human user, a machine user, etc.) to enter one of or a combination of data or commands into the programmable circuitry 1012. The input device(s) 1022 can be implemented by, for example, one of or a combination of an audio sensor, a microphone, a camera (still or video), a keyboard, a button, a mouse, a touchscreen, a trackpad, a trackball, an isopoint device, or a voice recognition system.

One or more output devices 1024 are also connected to the interface circuitry 1020 of the illustrated example. The output device(s) 1024 can be implemented, for example, by one of or a combination of display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, or speaker. The interface circuitry 1020 of the illustrated example, thus, includes one of or a combination of a graphics driver card, a graphics driver chip, or graphics processor circuitry such as a GPU.

The interface circuitry 1020 of the illustrated example also includes a communication device such as one of or a combination of a transmitter, a receiver, a transceiver, a modem, a residential gateway, a wireless access point, or a network interface to facilitate exchange of data with external machines (e.g., computing devices of any kind) by a network 1026. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 1000 of the illustrated example also includes one or more mass storage discs or devices 1028 to store one or more of firmware, software, or data. Examples of such mass storage discs or devices 1028 include one or more magnetic storage devices (e.g., floppy disk, drives, HDDs, etc.), optical storage devices (e.g., Blu-ray disks, CDs, DVDs, etc.), RAID systems, or solid-state storage discs or devices such as flash memory devices and SSDs.

The machine-readable instructions 1032, which may be implemented by the machine-readable instructions of FIGS. 6, 7, and 9, may be stored in one of or a combination of the mass storage device 1028, in the volatile memory 1014, in the non-volatile memory 1016, or on at least one non-transitory computer readable storage medium such as a CD or DVD which may be removable.

While an example manner of implementing the deserializer circuitry 202 of FIG. 1 is illustrated in FIGS. 3 and 4, one or more of the elements, processes, or devices illustrated in FIGS. 3 and 4 may be combined, divided, re-arranged, omitted, eliminated, or implemented in any other way. Further, the PLL circuitry 302, the controller circuitry 304, the BC TX circuitry 306, the FC RX circuitry 308, or, more generally, the example deserializer circuitry 202 of FIGS. 3 and 4, may be implemented by hardware alone or by hardware in combination with software and firmware. Thus, for example, any of the PLL circuitry 302, the controller circuitry 304, the BC TX circuitry 306, the FC RX circuitry 308, or, more generally, the example deserializer circuitry 202, could be implemented by programmable circuitry in combination with one or more machine-readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), or field programmable logic device(s) (FPLD(s)) such as FPGAs. Further still, the example deserializer circuitry 202 of FIGS. 3 and 4 may include one or more elements, processes, or devices in addition to, or instead of, those illustrated in FIGS. 3 and 4, or may include more than one of any or all of the illustrated elements, processes and devices.

Flowcharts representative of example machine-readable instructions, which may be executed by programmable circuitry to at least one of implement or instantiate the deserializer circuitry 202 of FIGS. 3 and 4 or representative of example operations which may be performed by programmable circuitry to at least one of implement or instantiate the deserializer circuitry 202 of FIGS. 3 and 4, are shown in FIGS. 6, 7, and 9. The machine-readable instructions may be one or more executable programs or portion(s) of one or more executable programs for execution by programmable circuitry such as the programmable circuitry 1012 shown in the example programmable circuitry platform 1000 described below in connection with FIG. 10 and may be one or more function(s) or portion(s) of functions to be performed by the example programmable circuitry (e.g., an FPGA). In some examples, the machine-readable instructions cause an operation, a task, etc., to be carried out or performed in an automated manner in the real-world. As used herein, “automated” means without human involvement.

The program may be embodied in instructions (e.g., software and/or firmware) stored on one or more non-transitory computer readable and/or machine-readable storage medium such as one of or a combination of cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), or any other storage device or storage disk. The instructions of the non-transitory computer readable and/or machine-readable medium may program or be executed by programmable circuitry located in one or more hardware devices, but the entire program or parts thereof could alternatively be executed or instantiated by one or more hardware devices other than the programmable circuitry or embodied in dedicated hardware. The machine-readable instructions may be distributed across multiple hardware devices or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIGS. 6, 7, and 9, many other methods of implementing the example deserializer circuitry 202 may alternatively be used. For example, the order of execution of the blocks of the flowchart(s) may be changed, or some of the blocks described may be changed, eliminated, or combined. Also or alternatively, any or all of the blocks of the flow chart may be implemented by one or more hardware circuits (e.g., processor circuitry, discrete, integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations or local to one or more hardware devices (e.g., a single-core processor (e.g., a single core CPU), a multi-core processor (e.g., a multi-core CPU, an XPU, etc.)). For example, the programmable circuitry may be one of or a combination of a CPU or an FPGA located in the same package (e.g., the same integrated circuit (IC) package or in two or more separate housings), one or more processors in a single machine, multiple processors distributed across multiple servers of a server rack, multiple processors distributed across one or more server racks, etc., or any combination(s) thereof.

The machine-readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, or produce machine executable instructions. For example, the machine-readable instructions may be fragmented and stored on one or more storage devices, disks or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., in order to render them directly readable, interpretable, or executable by a computing device or other machine. For example, the machine-readable instructions may be stored in multiple parts, which are individually compressed, encrypted, or stored on separate computing devices. The parts, when decrypted, decompressed, or combined, form a set of one or more computer-executable or machine executable instructions that implement one or more functions or operations that may together form a program such as that described herein.

In another example, the machine-readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before the machine-readable instructions or the corresponding program(s) can be executed in whole or in part. Thus, machine-readable, computer readable or machine-readable media, as used herein, may include one or a combination of instructions and program(s) regardless of the particular format or state of the machine-readable instructions or program(s).

The machine-readable instructions described herein can be represented by any past, present, or future instruction language, scripting language, programming language, etc. For example, the machine-readable instructions may be represented using any of the following languages: C, C++, Java, C#, Perl, Python, JavaScript, HyperText Markup Language (HTML), Structured Query Language (SQL), Swift, etc.

As mentioned above, the example operations of FIGS. 6, 7, and 9 may be implemented using executable instructions (e.g., computer readable and/or machine-readable instructions) stored on one or more non-transitory computer readable or machine-readable media. As used herein, the terms non-transitory computer readable medium, non-transitory computer readable storage medium, non-transitory machine-readable medium, and non-transitory machine-readable storage medium are expressly defined to include any type of computer readable storage device or storage disk and to exclude propagating signals and to exclude transmission media. Examples of such non-transitory computer readable medium, non-transitory computer readable storage medium, non-transitory machine-readable medium, or non-transitory machine-readable storage medium include one or more optical storage devices, magnetic storage devices, an HDD, a flash memory, a read-only memory (ROM), a CD, a DVD, a cache, a RAM of any type, a register, or any other storage device or storage disk in which information is stored for any duration (e.g., for extended time periods, permanently, for brief instances, for temporarily buffering, for caching of the information). As used herein, the terms “non-transitory computer readable storage device” and “non-transitory machine-readable storage device” are defined to include any physical (mechanical, magnetic, electromechanical, or electrical) hardware to retain information for a time period, but to exclude propagating signals and to exclude transmission media. Examples of non-transitory computer readable storage devices or non-transitory machine-readable storage devices include one or a combination of random-access memory of any type, read only memory of any type, solid state memory, flash memory, optical discs, magnetic disks, disk drives, or redundant array of independent disks (RAID) systems. As used herein, the term “device” refers to physical structure such as one of or a combination of mechanical, electromechanical, or electrical equipment, hardware, or circuitry that may or may not be configured by computer readable instructions, machine-readable instructions, etc., or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description.

Modifications are possible in the described embodiments, and other embodiments are possible, within the scope of the claims.

From the foregoing, it will be appreciated that example systems, apparatus, articles of manufacture, and methods have been described that characterize cable faults. Described systems, apparatus, articles of manufacture, and methods improve the efficiency of using a computing device by disabling one more operations during normal communications, transmitting a signal across the coaxial cable, measuring the reflected signal that returns, and using the presence, amplitude, and other characteristics of the reflected signal to determine one or more of: whether a fault exists on the cable, whether the fault is an open circuit or a closed circuit, and where the fault is located on the cable. Accordingly, the deserializer circuitry described herein can troubleshoot cable faults with more detail, less time, and less complexity than other vehicle systems. Described systems, apparatus, articles of manufacture, and methods are also directed to one or more improvement(s) in the operation of a machine such as a computer or other electronic, electromechanical, or mechanical device.

What is claimed is:

1. An apparatus comprising:
transmitter circuitry having an input and an output;
receiver circuitry having an input coupled to the output of the transmitter circuitry, and an output; and
controller circuitry having an input coupled to the output of the receiver circuitry and an output coupled to the input of the transmitter circuitry;
the controller circuitry configured to:
instruct the transmitter circuitry to transmit a signal; and
determine, responsive to a voltage received at the output of the receiver circuitry after the transmission of the signal, when a fault exists in a cable coupled to the output of the transmitter circuitry.

2. The apparatus of claim 1, wherein the control circuitry is configured to detect whether the fault is an open circuit or a short circuit.

3. The apparatus of claim 1, wherein the controller circuitry is configured to detect a location of the fault on the cable.

4. The apparatus of claim 1, wherein the cable is a coaxial cable used to:
support bi-directional communications between the apparatus and an external device coupled to the cable; and
power the external device.

5. The apparatus of claim 4, wherein:
the transmitter circuitry implements back-channel communications with the external device by performing serializer operations; and
the receiver circuitry supports forward-channel communications with the external device by performing deserializer operations.

6. The apparatus of claim 4, wherein:
the transmitter circuitry implements forward-channel communications with the external device by performing serializer operations; and
the receiver circuitry supports back-channel communications with the external device by performing deserializer operations.

7. The apparatus of claim 1, wherein the receiver circuitry further includes:
echo cancellation circuitry having a first input coupled to the transmitter circuitry, a second input coupled to the output of the transmitter circuitry, and an output;
equalization circuitry having an input coupled to the output of the echo cancellation circuitry and an output;
variable gain adapter (VGA) circuitry having an input coupled to the output of the echo cancellation circuitry and an output; and
slicer circuitry having a first input coupled to the output of the VGA circuitry, a second input, and an output.

8. Controller circuitry configured to:
instruct transmitter circuitry within a device to perform operations, the transmitter circuitry coupled to a cable interface terminal;
responsive to the operations, instruct receiver circuitry within the device to measure a voltage, the receiver circuitry also coupled to the cable interface terminal; and
determine, responsive to the measured voltage, when a fault exists on a cable that is coupled to the cable interface terminal.

9. The controller circuitry of claim 8, wherein to determine the fault exists, the controller circuitry is configured to:
instruct the transmitter circuitry to transmit a message to an external device via the cable interface terminal, the message instructing the external device to stop communications;
measure, using the receiver circuitry, an amplitude of a back-channel echo voltage on the cable interface terminal, the back-channel echo voltage caused by the transmission of the message; and
determine the amplitude is above a threshold voltage.

10. The controller circuitry of claim 8, further configured to determine:
a type of the fault; and
a location of the fault.

11. The controller circuitry of claim 10, wherein to determine the type of fault, the controller circuitry is configured to:
instruct the transmitter circuitry to transmit a voltage step signal on the cable interface terminal, the voltage step signal to reflect at the fault and travel back towards the device; and
measure, using the receiver circuitry, a polarity of the reflected voltage step signal.

12. The controller circuitry of claim 11, further configured to identify the type of fault as an open circuit responsive to the reflected voltage step signal having a positive polarity.

13. The controller circuitry of claim 11, further configured to identify the type of fault as a short circuit responsive to the reflected voltage step signal having a negative polarity.

14. The controller circuitry of claim 11, wherein to measure the polarity of the reflected voltage step signal, the controller circuitry is configured to compare a magnitude of the reflected voltage step signal to a threshold voltage.

15. The controller circuitry of claim 10, wherein to determine the location of the fault, the controller circuitry is configured to:
instruct the transmitter circuitry to transmit a voltage pulse on the cable interface terminal;
measure an amount of time that passes between: a) when the transmitter circuitry transmits the voltage pulse, and b) when the receiver circuitry receives a reflected version of the voltage pulse; and
determine a distance responsive to: a) the amount of time and b) a propagation delay of the cable.

16. The controller circuitry of claim 15, wherein, before instructing the transmitter circuitry to transmit the voltage pulse, the controller circuitry is configured to:
disable phase interpolation, echo cancellation, and equalization operations performed by the receiver circuitry; and
set a variable gain amplifier (VGA) circuit within the receiver circuitry to an increased gain value to enable detection of the reflected version of the voltage pulse.

17. The controller circuitry of claim 15, wherein:
the distance is a round-trip value including: a) a distance travelled by the voltage pulse from the cable interface terminal to the fault on the cable, and b) a distance travelled by the reflected version of the voltage pulse from the fault to the cable interface terminal; and
the controller circuitry is configured to determine the location of the fault by determining half of the distance.

18. A system comprising:
serializer circuitry having an interface terminal;
a cable having:
a fault;
a first terminal coupled to the interface terminal of the serializer circuitry; and
a second terminal; and
deserializer circuitry having an interface terminal coupled to the second terminal of the cable, the deserializer circuitry configured to determine:
the fault exists within the cable;
a type of the fault; and
a location of the fault.

19. The system of claim 18, wherein:
the cable is a Shielded Twisted Pair;
the system further includes:
camera circuitry coupled to an input terminal of the serializer circuitry; and
image signal processor (ISP) circuitry coupled to an input terminal of the deserializer circuitry;
wherein the cable is configured to support bi-directional communication including:
forward-channel communications from the ISP circuitry to the camera circuitry; and
back-channel communications from the camera circuitry to the ISP circuitry.

20. The system of claim 19, wherein to detect the existence, type, and location of the fault, the deserializer circuitry is configured to:
transmit a signal across the cable using the interface terminal; and
measure a reflected version of the signal at the interface terminal, wherein one or more of an amplitude, polarity, or timing of the measurement is responsive to a characteristic of the fault.
